(19) United States
(12) Patent Application Publication
(10) Pub. No.: US 2024/0345348 A1
(43) Pub. Date: Oct. 17, 2024

(54) PHOTON INFORMATION FIELD ENABLING MULTIPLE DYNAMIC INTERCONNECTIONS IN A CLUSTER OF PROGRAMMABLE OPTOELECTRONIC MODULES

(71) Applicant: Valère Fontaine-Picoureix, Montreuil (FR)

(72) Inventor: Valère Fontaine-Picoureix, Montreuil (FR)

(21) Appl. No.: 18/579,597

(22) PCT Filed: Jul. 15, 2022
(86) PCT No.: PCT/FR2022/051422

§ 371 Date: Jan. 26, 2024

(30) Foreign Application Priority Data
Jul. 16, 2021 (FR) FR2107714

(51) Int. Cl. G02B 6/43; G02B 6/42; H04Q 11/00

(52) U.S. Cl. CPC G02B 6/43; G02B 6/4206; G02B 6/421; G02B 6/4214; G02B 6/428; H04Q 11/0005

(57) ABSTRACT

A cluster of optronic modules includes an optronic circuit comprising a printed circuit formed by an insulating plate having conductive tracks; and optronic modules. The optronic modules include metal pins comprising at least one digital signal input/output pin, a ground pin and a power supply pin; and at least one optical connector for the input/output of a bidirectional light signal.

### CROSS-REFERENCE TO RELATED APPLICATIONS

This application is a national phase entry under 35 U.S.C. § 371 of International Patent Application PCT/FR2022/051422, filed Jul. 15, 2022, designating the United States of America and published as International Patent Publication WO 2023/285770 A1 on Jan. 19 2023, which claims the benefit under Article 8 of the Patent Cooperation Treaty of French Patent Application Serial No. FR2107714, filed Jul. 16, 2021.

### TECHNICAL FIELD

The present disclosure relates to the fields of optronics combining electronics, optics, and photonics. It relates more particularly to electronic components that emit or interact with light and the physical, photonic and computer architectures of optronic modules.

### BACKGROUND

Printed circuit boards (PCBs) are traditionally made up of an insulating plate on which copper traces conducting the electricity are etched or deposited, allowing electrons to circulate freely in the circuit formed by the conductive traces. Electrons are negatively charged particles that interact with each other and with other particles. These interactions slow down the electrons in their movement within the integrated circuits, limit the amount of information that can be transmitted, and generate heat, which leads to a loss of energy. A heat sink or another cooling technique is usually necessary to regulate heat generation, without which, electrical components risk undergoing irreversible damage.

More recently, photonic integrated circuits have been proposed that use photons, massless elementary particles that representing a quantum energy of light, instead of electrons. Photons move at the speed of the light in the transmission medium, and do not interfere substantially with one another. This advantage makes it possible to significantly increase the bandwidth and the speed of the circuit, while greatly reducing the loss of energy, for better energy efficiency. These photonic integrated circuits comprise waveguides replacing the conductive traces of the prior circuits.

Multiplexing techniques make it possible to send a very large number of signals through these single-mode waveguides, exceeding the number of signals that can be transmitted through copper by several orders of magnitude.

A hybrid solution has also been proposed that combines a photonic circuit and a conventional PCB, in particular, in the telecommunications sector, where high-speed information is transmitted via optical fiber waveguides before being converted into digital signals that can be processed by the usual electronic devices, since the conventional energy infrastructures and data networks exist on electrical structures, but not on photonic structures.

In the prior art, the application of US patent US20060159387A1 describing a photonic integrated circuit (PIC) device is known. The PIC device comprises a set of optical transceivers comprising optical transmitters and optical receivers, and an integrated optical interconnection mesh functionally associated with the set of optical transceivers and structured to allow at least one of the following network architectures: a star network architecture, a bus/broadcast network architecture network, and a ring network architecture.

This prior art document describes a PIC in which several light sources (VCSELs with fixed wavelength and VCSELs with variable wavelength) are integrated, as well as light receivers (PIN diodes, Avalanche diodes). The integration of the components without any other alternative in the PIC chip have made it obsolete due to constant progress. This is a major drawback with regard to the costs of production that such a device would today entail, in comparison with more recent technologies, for example, based on nanomaterials/nano-wires for the production of single or multi-chromatic light sources, modulators, or light wave detectors.

Advantageously, several variants of the present disclosure can benefit from these new methods, by externalizing the light sources instead of integrating them. Thus, the present disclosure offers several alternatives in order to avoid obsolescence and retain its appeal as progress continues in the future. This also offers an alternative to the optical receivers, which may be replaced by resonator resonators coupled to germanium diodes, which are much smaller and less expensive than the assembly consisting of “mirrors-prism-lenses-and avalanche diodes” of the prior art.

The integration of numerous transmitters and associated optical receivers (transceivers) has led to other major drawbacks that the present disclosure eliminates, such as:
Complex manufacturing due to the numerous components to be integrated and to be interconnected in a fixed manner in the PIC,
The inability to share the light source to share it between a plurality of programmable optoelectronic modules, since the prior art does not provide other options than to be fully integrated into each PIC.
A large surface area occupied on the substrate of the PIC chip measured in mm², this being against the constant trend of miniaturization that has been the main source of progress in the field.

This PIC additionally incorporates an interconnection mesh so that the numerous components that it integrates are placed into an internal network (star network, bus/broadcast network, ring network) while the present disclosure actually makes it possible to instead create an external network of dynamic interconnections of optronic modules forming a cluster.

Therefore, the solution proposed by this document is complex and not very flexible, resulting in a high manufacturing cost compared to the present disclosure, which is based on simplicity, flexibility, and low-cost scalability.

Patent application JP2007334196 describes an optical bus provided with a central layer sandwiched between two layers of cladding formed in a planar shape. An optical propagation layer is intended for optical propagation in a direction along a plane, with an optical injection section inserted at a location of this optical propagation layer to inject light therein, and an optical extraction section inserted into a plurality of locations of the optical propagation layer to extract the light injected from the optical injection section and propagated within the optical propagation layer. It is therefore a matter of one-way connections, from an injector to a plurality of extractors. These layers or plates are also partitioned into a plurality of areas, and/or stacked together, in order to be able to transmit several distinct data streams without mixing them. Finally, the use of predetermined color injectors, associated with predetermined selective filter extractors, allows a plurality of fixed, always one-way connections, propagated within the same plate.

Also known is patent application US20140055873A1 describing pressure-adjusted optical vias for interconnecting different levels of an electronic or electro-optical device, a printed circuit board or a connector. These vias have a very narrow angular emission limiting their use to point-to-point interconnections connected by conventional waveguides. The information field of the present disclosure incidentally makes it possible to overcome this limitation.

Patent application US2,04096152 describes an optical connection device for optically coupling light propagated through an optical waveguide to an optical element arranged outside the optical waveguide and with the following configuration. Part of the optical waveguide is removed so as to be shaped like a groove.

Patent application US2018246284 relates to a system for communicating optical signals, comprising:
a first embedded optical transceiver system (E-OTRX) comprising an optical transceiver configured to transmit a beam of light in a first direction;
a second E-OTRX having an optical transceiver configured to receive light; and
a multilayer printed circuit board (PCB) attached to the first E-OTRX and the second E-OTRX, the multilayer PCB comprising a first opening facing the first E-OTRX and a second opening facing the second E-OTRX, and the multilayer PCB further comprising a first layer, a second layer, a transparent layer between the first layer and the second layer, the transparent layer comprising a first compartment, a first mirror (214) disposed in the first compartment of the transparent layer and in the first opening of the multilayer PCB and a second mirror disposed in the first compartment of the transparent layer and in the second opening of the multilayer PCB.

The solutions of the prior art certainly make it possible to increase the information flow rate through the use of optical waves in place of electrically conductive traces, but each proposed solution has limitations and/or drawbacks, which the present disclosure advantageously makes it possible to dispense with.

Hybrid boards integrating copper traces with light guides are much more difficult to produce than traditional copper-trace boards.

Hybrid boards are also totally fixed at the time of their manufacture. Unlike conductive-trace printed circuit boards in which an error in the drawing of the traces could easily be corrected by scraping a trace or by connecting two traces with a metal bridge, optical waveguide boards do not allow any modification of the topology after having been manufactured.

Moreover, the fixed state of optical waveguide boards, whether hybrid or purely optical, does not allow the dynamic interconnection of independent optoelectronic modules distributed within a given scope according to various topologies, which contrarily is easy to achieve instantaneously, thanks to the present disclosure. Since prior art solutions lack information fields in the sense of the present disclosure, certain interconnection topologies between independent optoelectronic modules (e.g., mesh, extended star, etc.) are not only fixed, but also complex and costly to implement.

### BRIEF SUMMARY

The present disclosure aims to overcome the disadvantages of the prior art by proposing a technical solution that makes it possible to instantly implement, without additional expense, a wide range of dynamic interconnection topologies between programmable optoelectronic modules distributed within a defined perimeter forming a cluster.

By way of non-limiting example, the topologies of the cluster of interconnected optronic modules can dynamically adopt the following architectures: Bus network, star network, ring, dual ring, tree topology, mesh, fully connected, extended star, hybrid topology, etc.

The present disclosure relates to a cluster of optronic modules comprising at least two modules having the technical features set forth in claim 1.

A cluster according to the present disclosure comprises various elements:
a) A multilayer optronic circuit;
b) Optronic modules consisting of electronic and photonic components assembled in 2D or 3D; and
c) Optical link couplers between the optronic modules and the multilayer optronic circuit, which may, for example, be vias, fibers, optical lenses, as well as nanostructured optical materials.

### First Element: a Multilayer Optronic Circuit

The multilayer optronic circuit comprises:

1. a surface layer formed by a printed circuit board formed by an insulating plate having conductive traces;

2. at least one transparent optical layer constituting an information field (in the sense of this patent, an information field is a volume inside which the information propagates in the form of light radiation modulated, in any direction in a plane perpendicular to optical couplers for interfacing with the optronic modules, and parallel to the plane of the printed circuit);

Preferably, the lateral edges of this optical layer are treated in a non-reflective manner, by an absorbent coating, or dichroic coatings or by a diffusing treatment, in the wavelength bands used by the optronic modules; and

3. optionally an opaque layer on the side opposite the printed circuit board, this opaque layer being able to be a second printed circuit board.

### Second Series of Elements: Optronic Modules

The optronic modules comprise a housing having at its lower surface:
a. metal pins comprising at least one input-output pin of a digital signal, a ground pin and a power supply pin, and
b. at least one optical coupler for the input-output of a bidirectional light signal via one of the couplers.

An optronic module according to the present disclosure comprises at least one multi-spectral light emitter and/or at least one multi-spectral optical sensor optically connected to the optical coupler on the one hand, and electrically to the metal pins by means of an electronic circuit comprising electronic components, in particular modulators, amplifiers, microcontrollers, etc.

These optronic modules consist of a set of photonic components connected to a set of electronic components. These two complementary assemblies can be connected side by side in 2D or superimposed in 3D to form the module.

These optronic modules being programmable by electrical signals received on the at least one input-output pin of a digital signal to control the selection of one or more active emission spectra of the multi-spectral light emitter and to control the selection of one or more active emission spectra of the at least one multi-spectral optical sensor.

### Third Series of Elements: Optical Link Couplers

These optical couplers consist of transparent pins of which one of the ends is complementary to the optical connectors of the optronic modules and the other end comprises a reflective inverted cone whose tip is directed toward the optronic module and concentric with the longitudinal axis of the optical via, the slope of the reflective surface being 45° to omnidirectionally reflect light from the optical connector of the optronic module in the plane of the three-dimensional transparent information field and/or to transmit, along the longitudinal axis of the via, the light coming from any direction of the information field and reflected by the reflective conical surface.

These pins are designed to be engaged in the optronic circuit, to penetrate the optical layer, perpendicularly to the transverse plane of the optronic circuit to ensure optical coupling with the optical connector of an optronic module.

According to a preferred embodiment, the printed circuit board comprises conductive traces comprising conductive power traces for the power supply of the optronic modules and conductive link traces for the transmission of digital data with the optronic modules.

According to one alternative, the printed circuit board comprises only conductive power supply traces, the digital data being transmitted by a PWM (Pulse Width Modulation) type of power supply signal.

According to one variant, the printed circuit board comprises at least one optical coupler for connecting an optical fiber to the information field.

According to a second variant, the printed circuit board comprises at least one optical coupler for connecting to the information field an optical via ensuring the input-output of a bidirectional light signal between the information field and a peripheral optronic device.

According to one particular embodiment, the printed circuit board comprises at least two parallel three-dimensional transparent information fields, and wherein at least part of the vias comprise a masking ring whose position corresponds to one of the at least two three-dimensional transparent information fields.

The optronic modules comprise at least one optical coupler to which it is possible to connect: Either an optical fiber associated with the information field in its “solid” version (consisting of a solid made of glass, acrylic, polycarbonate), or an optical via associated with the information field in its gaseous version (cavity filled with air or gas, etc.).

The present disclosure also relates to a via for the interconnection of an optronic circuit and an optronic module to produce an optical coupling characterized in that it consists of a tubular segment of optical fiber or a tube filled with air, one of the front ends of which is covered by a lens and the other end has a reflective cone coaxial with the segment and has a slope of 45°.

The present disclosure also relates to an optronic circuit for the production of an optronic module characterized in that it comprises light-emitting diodes and photoreceptors associated with chromatic filters as well as an electronic controller that can be configured by an electrical signal transmitted by printed circuit, the controller controlling the configuration to determine the active light-emitting diode(s) for the emission of data by the optronic module considered, as well as the active filter(s) for the demultiplexing of the data by this optronic module.

### BRIEF DESCRIPTION OF THE DRAWINGS

The present disclosure will be better understood on reading the following description, which concerns a non-limiting exemplary embodiment that is shown by the appended drawings, in which:

FIG. 1 shows a schematic sectional view of a circuit forming a cluster of optronic modules according to the present disclosure;

FIG. 2 shows a schematic sectional front view of a via according to the present disclosure;

FIG. 3 shows a schematic sectional side view of a via according to the present disclosure;

FIG. 4 shows a schematic view of a cluster of optronic modules interconnected in a three-dimensional information field by positioning couplers between vertical and horizontal light fluxes;

FIG. 5 shows a schematic view of the hardware architecture of an optronic module;

FIG. 6 shows a schematic view of the hardware architecture of an optical electronic and coupling module of the transceiver type;

FIG. 7 shows a schematic sectional side view of an optical link coupler according to the present disclosure;

FIG. 8 shows a schematic sectional view of a preferred alternative of the optronic plate for optronic modules that are powered via a shared external light source according to the present disclosure;

FIG. 9 shows a schematic view of a first alternative of a cluster of optronic modules interconnected in a bidirectional information field according to the present disclosure;

FIG. 10 shows a schematic view of a second alternative of a cluster of optronic modules interconnected in a bidirectional information field according to the present disclosure;

FIG. 11 shows a schematic view of an alternative of a cluster of optronic modules interconnected in a bidirectional information field according to the present disclosure; and

FIG. 12 shows an assembled schematic view of the cluster of optronic modules interconnected in a bidirectional information field according to the present disclosure.

### DETAILED DESCRIPTION

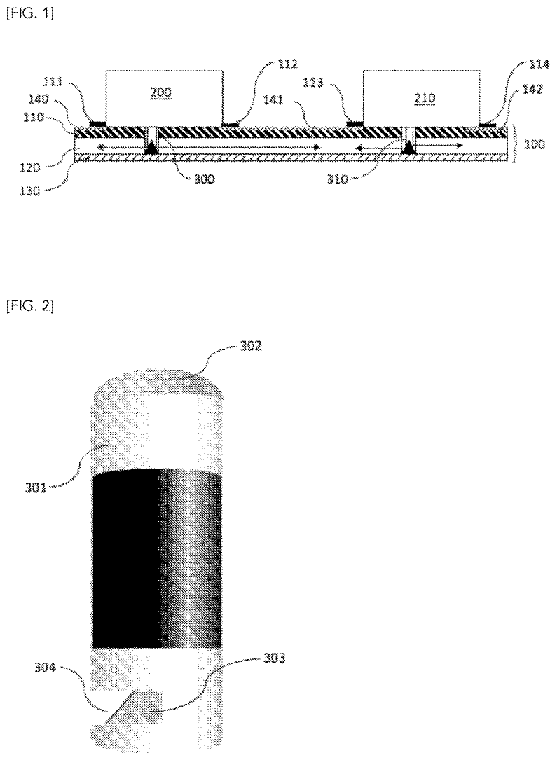

FIG. 1 shows the general principle of the present disclosure. It constitutes a cluster of optronic modules (200, 210), fixed to an optronic circuit (100) formed by a multilayer assembly of a plate (110) consisting of an insulating material, one or more transparent flat strips (120) or strips delimiting a cavity filled with air or an inert gas, and an opaque plate (130). Metal traces (140 to 142) are formed on the insulating material (110), as is customary for a usual electronic printed circuit board. The printed circuit board (110) is formed by an insulating plate traditionally an epoxy resin or a sheet of BAKELITE®, and more generally any known material for producing a printed circuit board.

The transparent layer(s) (120) form an information field allowing the propagation of the light in this volume having a height of a few millimeters, typically about 10 millimeters. It is either formed by a hollow chamber, or by a transparent material.

The information field (120) is according to a first variant formed by a hollow volume located between the printed circuit board (110) and a non-reflecting closing plate (130), connected by a peripheral edge whose inner surface is non-reflecting. This hollow volume contains air or optionally an inert gas such as argon, krypton or xenon.

This information field (120) may also be formed according to a second variant by a transparent material. It can be attached directly to the insulating material of the plate (110). It is also possible to provide an opaque coating, in the form of a varnish, for example, between the transparent layer (120) and the insulating plate (110), and/or between two adjacent transparent layers (120). The exterior surface of the transparent layer (120) is coated with an opaque varnish (130).

In the case of a solid information field (120), the transparent material consists, for example, of a plate made of acrylic, glass, polycarbonate, with a thickness of 10 millimeters, for example. In this case, the space is defined by a peripheral frame, for example.

The side walls of the transparent layer (120) are coated with an opaque anti-reflective material.

The optronic modules (200, 210) are mounted on the optronic circuit (100) and are mechanically linked, for example, by clips attached to the insulating plate (110). These optronic modules (200, 210) have metal tabs (111 to 114) soldered to the conductive traces (140 to 142). These conductive traces (140 to 142) are, in particular, intended to electrically power the optronic modules (200, 210). These optronic modules comprise a controller and a memory as well as an optronic interface, to establish an optical communication in transmission and in reception, for example, via a light-emitting diode and an opto-electronic sensor, via an optical connector between the housing of the optronic module (200, 210) and the cavity of the information field (120).

The optical communication between the optronic modules (200, 210) and with peripherals is done via transparent layers (120), vias (300) consisting of an optical coupler described below.

### Detail of the Construction of the Vias

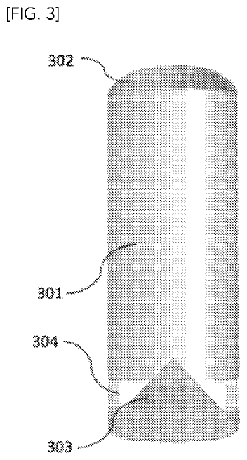

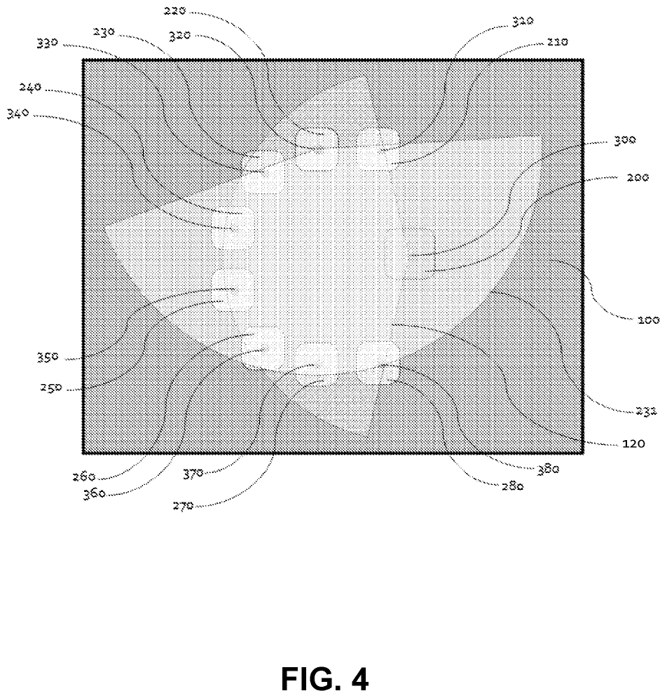

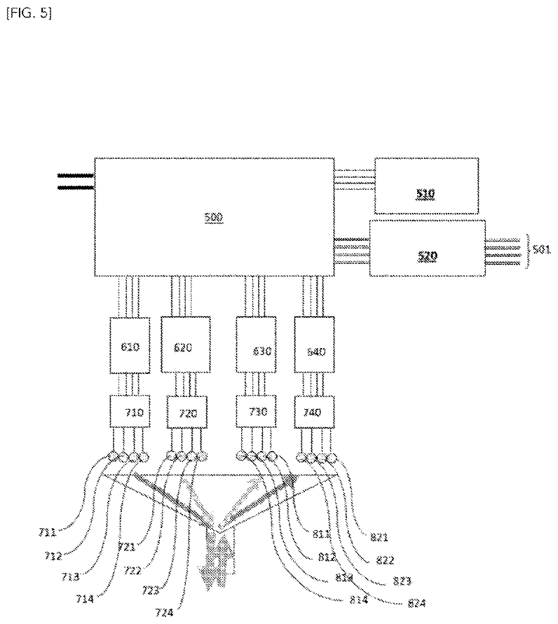

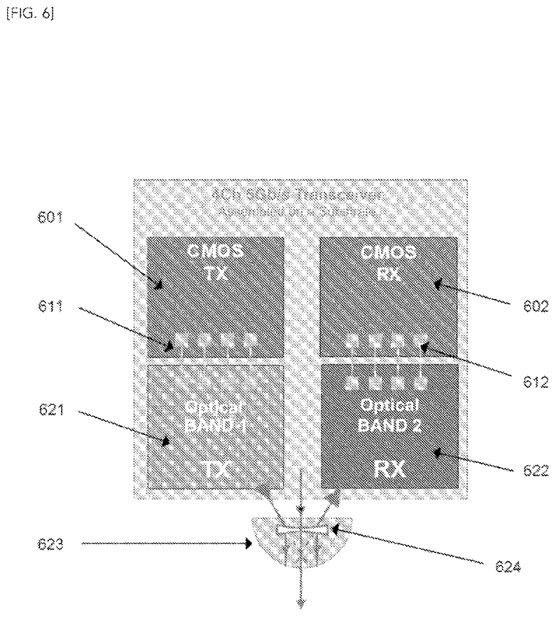

A via (300, 310), illustrated by FIGS. 2 and 3, consists of a tubular fiber segment or a tube filled with air (301) having a diameter of 5 millimeters, by way of example. One of the front ends of this segment (301) is covered by a lens (302). The other end has a reflective cone (303) formed, for example, by metallization of the surface of a conical bore made in the front end opposite the lens (302). This reflective cone (303) is coaxial with the segment (301) and has a slope of 45°. The segment (301) may have a window (304) opening over the height of the transparent layer (120), with an angular extent that is variable.

Alternatively, the reflective cone can be produced by a reflective insert having a polished-mirror surface.

### Location of the Optronic Modules (200)

The optronic modules (200 to 280) are fixed to the optronic circuit (100) forming a cluster (204). Each of the optronic modules (200 to 280) is optically connected to the information field (120) by an optical coupler (300 to 380). The organized distribution of the optronic modules (200 to 280) is configured to prevent the optical field of one via from being concealed by another via. In the example described, an optronic module (200), to which a “master” function is incorporated, is arranged at the center of an arc of a circle on which the other “slave” electronic modules (210 to 280) are arranged.

The gray area (208) represents the optical field of the via (300) of the master optronic module (200), which covers about 160°. The gray area (231) illustrates the optical field of the via (320) of one of the slave modules (220), also with an angular opening of about 160°.

The optronic modules (200 to 280) communicate with each other in optical mode, and are powered by the electrical traces (140 to 142) of the printed circuit board (110). These traces are also provided to transmit digital data, in particular, for programming and configuring optronic modules (200 to 280).

### Hardware Architecture of an Optronic Module (200 to 280)

According to an advantageous variant, the optronic modules (200 to 280) are all identical and are dynamically configurable by means of an electrical output bus, connected to the printed circuit board (110) by a tab of the optronic module (200 to 280).

An optronic module comprises a microcontroller (500) that can be programmed to analyze and produce electrical signals, so as to perform tasks. By way of example, it may be an FPGA configured in a microprocessor with several hundred MHz, an Atmel AVR microcontroller (ATmega328, ATmega32u4 or ATmega2560, or more powerful processors such as ARM Cortex-M 32 bits, 64 bits with over 100 MHZ), and complementary components that facilitate programming and interfacing with other circuits. Each module has at least one linear regulator and a quartz oscillator (or a ceramic resonator in certain models).

The microcontroller (500) is preprogrammed with bootloader firmware such that a dedicated scheduler is not necessary. The module also comprises a random-access memory (510) for loading a computer code via the serial inputs (501), which are connected to the conductive traces of the printed circuit board (110) of the optronic circuit.

Optionally, a device (520) compiles the programs downloaded via the serial inputs (501) into a command line for programming the microcontroller (500), such as a source code interpreter of a program.

Optionally, the module also comprises a radiofrequency circuit for the remote input-output of digital data.

The output data from the microcontroller (500) is transmitted over series links to shaping circuits (610, 620), which control modulation circuits (710, 720) controlling LEDs (711 to 714) and (721 to 724), respectively.

Four light-emitting diodes (711 to 714) emit in the example described in different wavelengths in the visible spectrum, for example:

| Color emitted | Wavelength peak |
|---|---|
| Green | 540 nm |
| Yellow | 580 nm |
| Orange | 640 nm |
| Red | 690 nm |

Four other light-emitting diodes (721 to 724) emit in the example described in different wavelengths in the infrared spectrum, for example, 750 nm, 810 nm, 860 nm and 910 nm.

This makes it possible to transmit information in different wavelength bands, depending on the information to be transmitted optically and the receiver equipment involved, in the same single information field (120).

The module also comprises a second pair of circuits comprising optronic sensors provided with filters in the visible (811 to 814) and in the infrared (821 to 824), in the same wavelengths as the aforementioned light-emitting diodes. The signals delivered by these sensors are processed by circuits (730, 740) and shaped by circuits (630, 640) to be transmitted on the serial inputs of the microcontroller (500).

Advantageously, in a variant of the example described above, it is equally possible to replace the light-emitting diodes with vertical cavity lasers (VECSEL) or ring resonator modulators (721 to 724), and ring resonator filters (811 to 824) when the light source is externalized. The optics can be adapted to suit the light source used.

### Modular Architecture

The combination of an optronic plate according to the present disclosure and a cluster of configurable optronic modules makes it possible to achieve very flexible electronic circuits on the basis of a very limited number “of universal components” due to the capacity to dynamically configure the interconnections by setting the transmission and reception wavelengths of each module, and of loading, via the electrical connection of the printed circuit board, sets of instructions enabling each module to be assigned a particular function, which can be dynamically modified at any time without requiring physical modification of the assembly.

In this way, it is even possible to provide “agnostic” assemblies that can be configured on demand, by clustering a series of modules on an optronic board, which the user can then configure by simply loading instructions that will determine the microcontroller's (500) functionalities, or by loading a data packet from a bitstream that configures an FPGA to select the optical transmission and reception bands, providing a kind of optronic alternative to the fixed copper-track links of a traditional printed circuit board (PCB).

The configuration of the optronic module consists of determining the light-emitting diode(s) (711 to 714) and (721 to 724) active for the transmission of data by the module considered, as well as the filter(s) (811 to 814) and (821 to 824) active for the reception of data by this module. Knowing the circuit topology on the one hand, and the total interconnection of the cluster of modules via the information space on the other, the user can choose the configuration they want by allocating to each module a transmission and a reception band or a combination of transmission and reception bands, independently of their physical location on the board. Of course, this considerably simplifies the drawing of the printed circuit board (110) since it comprises only power supply traces, which are not specific to a given module, and data transmission traces, which are not dependent on the module either, each module being programmed with a specific address making it possible to program the assembly using simple digital data sets.

### Allocating Bands to a Module

Let us consider two wave ranges, which will be referred to by convention as two sets of four “colors,” although our eyes will not be able to perceive all these “colors.”
A first range called “band 1” consists of four colors between 400 and 700 nm;
A second range called “band 2” consists of four colors between 800 and 1650 nm;

For each of these two bands, we have a transceiver set, namely TX (601) and RX (602). Each of these two sets TX (601) and RX (602) offer four distinct channels for transiting serial data streams. These four channels correspond to the four different colors used in each of the two strips. This represents 2×4=8 colors in total, all bands combined.

In order for the two-way data to be able to subsequently follow one and the same support to be conveyed, “the band 1” is assigned to a first direction of circulation, while the “band 2” is assigned to the opposite direction.

Two-way (Full Duplex) communication is thus obtained comprising four “away” channels and four “return” channels. These channels can thus intersect within a single optical guide, without merging via an optical block (623) comprising a converging lens (624).

This application is therefore defined by a modular transceiver assembled on substrate with the following features:
Two optical assemblies (621, 622) “Optical BAND 1 and Optical BAND 2”: Four Band 1 channels, and four band 2 channels (i.e., eight channels);
Two modules TX (601) and RX (602) “CMOS TX and CMOS RX” united in a single housing constituting a transceiver; and
Serial links (611, 612) to control the two optical assemblies (621, 622).

The optical assemblies (621, 622) are respectively light source modulators, and light wave demultiplexers. The light sources can be integrated into the optical assembly (621) (direct modulation) or externalized (indirect modulation). The light sources are, for example, VCSEL-based components or micro-LEDs.

The optical assemblies (621, 622) are produced by chips distinct from the electronic chips TX 601, RX 602. The chips are not encapsulated and the integration of the chips is done by wire bonding to form a monolithic and functional assembly.

### Optronic Link Couplers

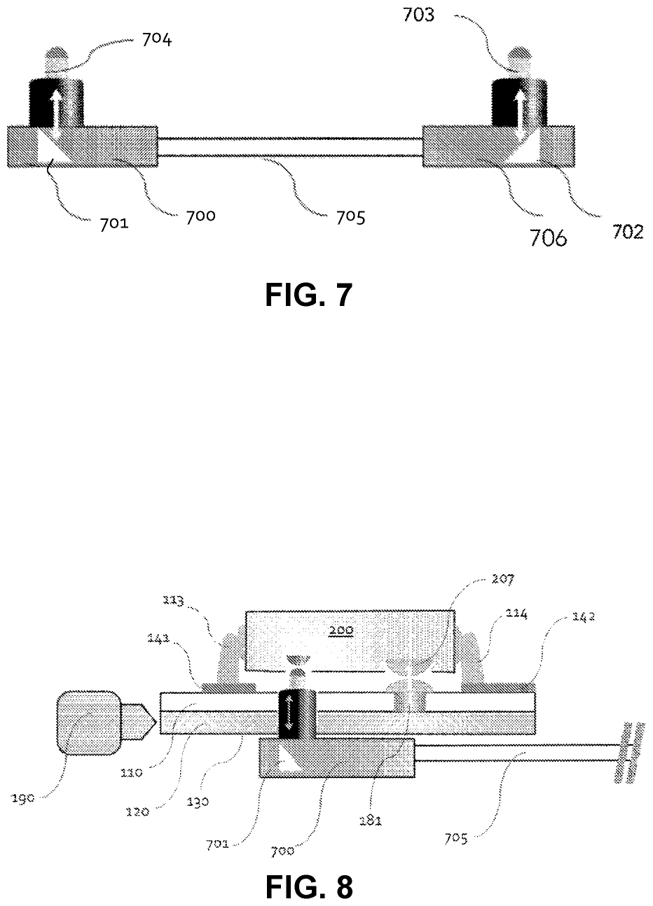

The optronic plate may be connected to another optronic plate or to an optronic peripheral by a coupler of which FIG. 7 represents a schematic sectional view.

It consists of two optronic connectors (700, 706) connected by an optical fiber (705). Each of the connectors comprises a prism (701, 702) returning the light to a fiber segment (703, 704) constituting an optical coupler that can be engaged in an optronic module to connect it to the volume of the information field (120).

### Variant Embodiment of the Optronic Plate

FIG. 8 shows a variant embodiment of an optronic plate according to the present disclosure. The multilayer assembly is formed of a plate (110) made of an insulating material, one or more transparent flat strips (120) and an opaque plate (130). The transparent plate (120), for example, made of plexiglass, transmits the light coming from a shared light source (190). As in the general example, metal pads (113 to 114) soldered to the conductive traces (141 to 142) are formed on the insulating material (110).

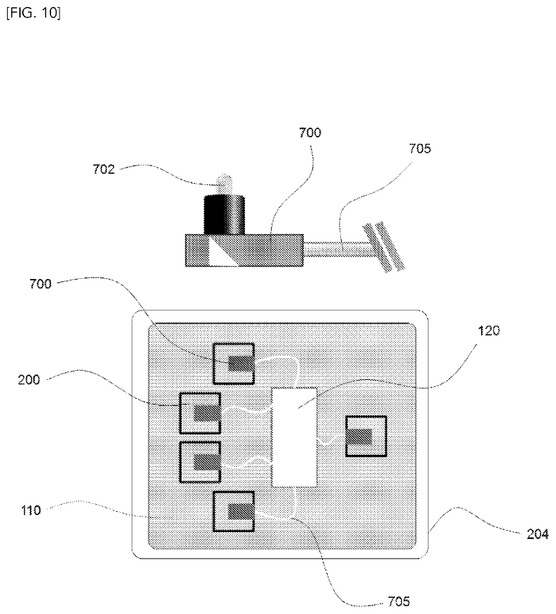

In this variant in FIG. 8, an optical connector and its optical fiber as described above in FIG. 7 are used to connect the optronic module (200) to the information field in its solid version, which is shown in FIG. 10.

The side walls of the transparent layer (120) are coated with an opaque anti-reflective material.

The light source (190) makes it possible to provide white light to the optronic module (200) via a coupler (181) and a lens (207) provided in the bottom of the optronic modules (200). This solution is intended for variants of optronic modules (200) made using silicon photonics, which are more compact than traditional optical techniques, advantageously avoiding the need to integrate light sources (LEDs, VCSELs, etc.) inside the optronic module (200).

### First Interconnection Variant of a Bidirectional Information Field

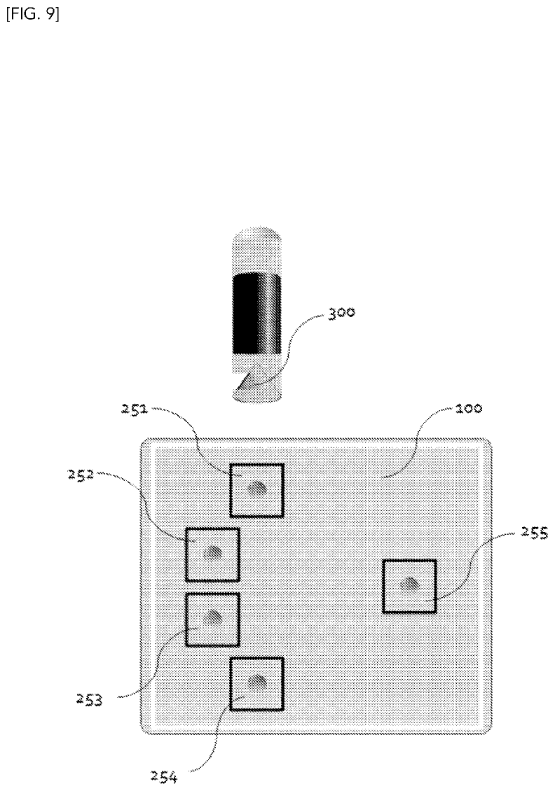

FIG. 9 shows a schematic view of a first interconnection variant of a bidirectional information field according to the present disclosure.

This variant relates to a cluster of modules interconnected by an information field (120) with a multitude of open-air optical links through vias (300). The optronic modules are arranged on the printed circuit in direct vision according to a location (251 to 255) providing a central hole for penetration of the via into the bidirectional information field. In this case, the bidirectional information field has the same surface as the printed circuit bearing the conductive traces to form a cluster of networked optronic modules.

### Second Interconnection Variant of a Bidirectional Information Field

FIG. 10 shows a schematic view of a second interconnection variant of a bidirectional information field according to the present disclosure.

According to this alternative embodiment, the optical link between the modules and the information field is realized by connectors comprising an optical fiber (705) and an optical coupler (702), for the link between an optronic module and the information field (120). The optronic modules (200) can thus be distributed with greater freedom on the surface of the printed circuit board (110), enabling the cluster (204) to be densified and the layout to be planned without optical constraints.

### Variant Embodiment of a Cluster According to the Present Disclosure

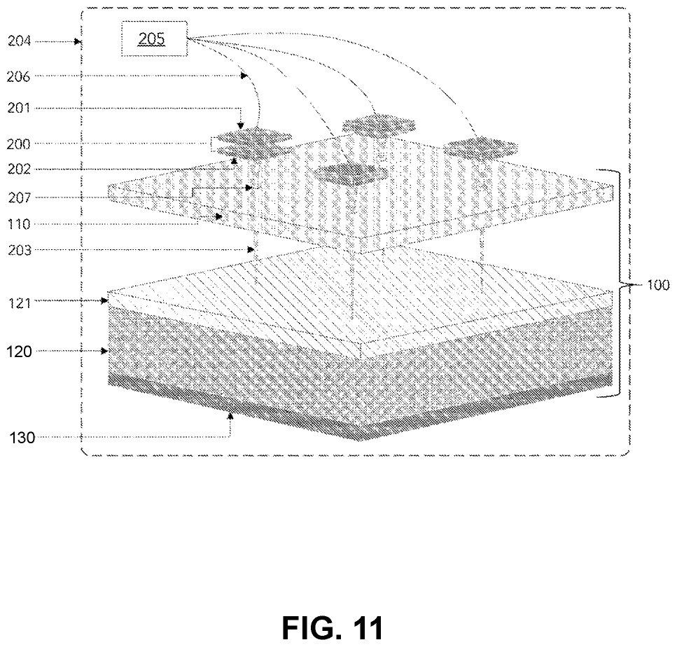

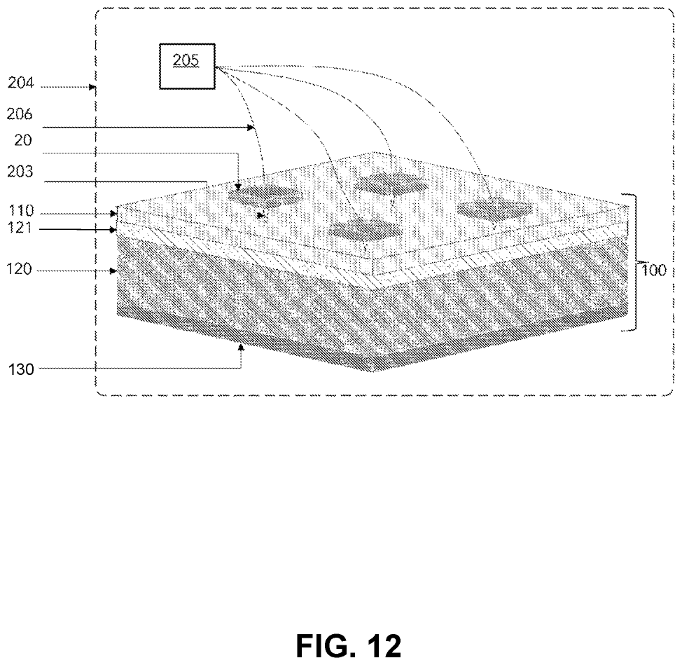

FIGS. 11 and 12 show a schematic view of a variant embodiment of a cluster (204) according to an advantageous embodiment of the present disclosure, respectively in an exploded view and an assembled view.

According to this variant, the optronic modules (200) consisting of a substrate of electronic components (201) and of a substrate of photonic components (202) do not comprise an integrated light source, but receive the light energy supplied by an external light source (205) via optical fibers (206) connected to the programmable optronic modules (200) by optical coupling.

Moreover, the interconnection between the programmable optronic modules (200) and the optronic circuit (100) is ensured not by vias, but by a collimated optical beam (203) transmitting the modulated light flux emitted by the optronic module (200). The return flow is received by diffusion from the anti-reflective surface (121). This anti-reflective surface (121) has, due to its structure, a high transmission power by vertical/planar coupling.

The printed circuit board (110) has small-diameter holes (207) for the passage of the light beams. Given that the optronic modules comprise very few metal pins, the copper traces are few and far between, leaving plenty of freedom to drilling holes over the entire surface constituting the cluster.

The information field (120) consists of a nanostructured medium with high light-wave propagation capability.

The lower surface of the information field (120) is coated with an opaque insulating surface (206) preventing any interaction between the information field (120) and the external environment.

1. A cluster of optronic modules, comprising:
a. an optronic circuit;
b. a plurality of optronic modules; and
c. optical link couplers,
wherein the optronic circuit is formed by a multilayer assembly comprising:
a printed circuit board formed by an insulating plate having electrical conductive tracks; and
at least one three-dimensional transparent layer forming a three-dimensional transparent information field allowing propagation of multi-spectral light in its volume by optical coupling perpendicular to a median plane of the three-dimensional transparent layer; and
wherein the optronic modules of the plurality comprise:
metal pins comprising at least one input-output pin of a digital signal, a ground pin and a power supply pin;
at least one optical coupler-for the-for input-output of a bidirectional light signal via one of-said-the optical link couplers;
at least one multi-spectral light emitter and/or at least one multi-spectral optical sensor optically connected to the one of the optical link couplers;
at least one multi-spectral light modulation means and at least one spectral filter associated with processing of the digital signal connected to at least one of optical link couplers between optronic modules and the three-dimensional transparent layer forming a three-dimensional transparent information field consisting of a volume inside which information propagates in the form of modulated light radiation, in any direction in a plane perpendicular to optical couplers for interfacing with the optronic modules, and parallel to the plane of the printed circuit board; and
a controller, a memory and signal amplifiers; and
the plurality of optronic modules being programmable by electrical signals received on the at least one input-output pin of a digital signal to control selection of one or more active emission spectra of the multi-spectral light modulation means and to control selection of one or more spectra of the at least one spectral filter.

2. The cluster of optronic modules according to claim 1, wherein the optical link couplers comprise vias penetrating into the three-dimensional transparent layer.

3. The cluster of optronic modules according to claim 2, wherein the optical link couplers comprise vias having one end complementary to optical connectors of the plurality of optronic modules and another end comprises a reflective surface of an inverted cone whose tip is directed toward the end and concentric with a longitudinal axis of the vias, a slope of the reflective surface being 45° to directionally reflect light from an optical connector of an optronic module in the volume of the three-dimensional transparent information field and/or to transmit, along the longitudinal axis of the vias, the light coming from any direction of the three-dimensional transparent information field and reflected by the reflective conical surface.

4. The cluster of optronic modules according to claim 1, wherein the optical couplers comprise an optical fiber section comprising a connector for optical coupling with the plurality of optronic modules, and a second connector for optical coupling with the three-dimensional transparent information field, a three-dimensional volume of which comprises a block of transparent material.

5. The cluster of optronic modules according to claim 1, wherein the plurality of optronic modules connected by the optical couplers in an information field can be interconnected by dynamic programming.

6. The cluster of optronic modules according to claim 5, wherein the plurality of optronic modules comprise means for modulating and filtering at least four wavelengths in at least two distinct bands of the spectrum.

7. An optronic module according to claim 1, wherein the printed circuit board comprises conductive tracks comprising conductive power tracks for supply of power to the plurality of optronic modules and conductive link tracks for transmission of digital data with the plurality of optronic modules.

8. An optronic module according to claim 1, wherein the printed circuit board comprises at least one optical coupler for connecting an optical fiber to the three-dimensional transparent information field.

9. An optronic module according to claim 2, wherein the printed circuit board comprises at least one optical coupler for connecting to the information field and an optical via configured for input and output of a bidirectional light signal between the information field and a peripheral optronic device.

10. An optronic module according to claim 2, wherein the optronic circuit comprises at least two parallel three-dimensional transparent information fields, and wherein at least part of the vias comprise a masking ring disposed at a position corresponding to one of the at least two parallel three-dimensional transparent information fields.

11. A via for interconnection of an optronic circuit and an optronic module to produce an optronic module according to claim 1, wherein the via comprises a tubular segment of optical fiber or a tube filled with air, one front end of which is covered by a lens and the other end has a reflecting cone coaxial with the tubular segment and has a slope of 45°.

12. An optronic module for production of a cluster of networked modules according to claim 1, wherein the optronic module comprises:
i. metal pins comprising at least one input-output pin of a digital signal, a ground pin and a power supply pin;
ii. at least one optical coupler for the input-output of a bidirectional light signal via one of the optical link couplers; and
iii. an optical coupler for the connection.

13. An optronic module for production of a cluster of networked modules according to claim 1, wherein the optronic module compriss:
iv. metal pins comprising at least one input-output pin of a digital signal, a ground pin and a power supply pin:
v. at least one optical coupler; and
vi. at least one coupler with an external light source.

14. The optronic module according to claim 13, further comprising modulators made of rings interposed between the external light source and the at least one optical coupler with the optronic circuit and spectral selective filters made of rings interposed between the at least one multi-spectral optical sensor and the at least one optical coupler with the optronic circuit.
